(19) United States
(12) Patent Application Publication
(10) Pub. No.: US 2023/0383405 A1
(43) Pub. Date: Nov. 30, 2023

(54) HAFNIUM PRECURSOR COMPOUND, COMPOSITION FOR FORMING HAFNIUM-CONTAINING FILM, COMPRISING SAME, AND METHOD FOR FORMING HAFNIUM-CONTAINING FILM

(71) Applicant: UP CHEMICAL CO., LTD., Pyeongtaek-si (KR)

(72) Inventors: Wonyong KOH, Yuseong-gu (KR); Jin Sik KIM, Pyeongtaek-si (KR); Byung Kwan KIM, Pyeongtaek-si (KR); Da Som YU, Pyeongtaek-si (KR); Jun Hwan CHOI, Goyang-si (KR)

(21) Appl. No.: 18/365,258

(22) Filed: Aug. 4, 2023

Related U.S. Application Data
(63) Continuation of application No. PCT/KR2022/001746, filed on Feb. 4, 2022.

(30) Foreign Application Priority Data
Feb. 4, 2021 (KR) 10-2021-0015965

(51) Int. Cl. C23C 16/455; C23C 16/40

(52) U.S. Cl. CPC C23C 16/45553; C23C 16/40

(57) ABSTRACT

The present disclosure relates to a hafnium precursor compound, a precursor composition for forming hafnium-containing film including the hafnium precursor compound and a method of forming a hafnium-containing film using the precursor composition.

### CROSS-REFERENCE TO RELATED APPLICATIONS

This application is a continuation of PCT Application No. PCT/KR2022/001746, filed on Feb. 4, 2022, which claims priority to Korean Patent Application Number 10-2021-0015965, filed on Feb. 4, 2021, both of which are hereby incorporated by reference in their entirety.

### TECHNICAL FIELD

The present disclosure relates to a hafnium precursor compound, a precursor composition for forming hafnium-containing film including the hafnium precursor compound and a method of forming a hafnium-containing film using the precursor composition for forming a film.

### BACKGROUND

Hafnium-containing oxide thin films are examples of the thin films which are essential for driving microelectronic devices such as non-semiconductors (logic) as well as semiconductors (DRAM, Flash Memory, ReRAM, PCRAM, etc.). Also, hafnium-containing oxide thin films have been used in a cutting-edge technology of organic light emitting diodes (OLEDs) in a display field. In a memory device, hafnium-containing oxide thin films have been used for a gate insulating film and a capacitor high-k film. In the display field, hafnium-containing oxide thin films have been evaluated as a high-k film of a storage capacitor in an OLED.

Currently, DRAM, Flash Memory, ReRAM, PCRAM in the memory field and Logic Memory in the non-memory field have reached physical limitations of two-dimensional structures, and in order to overcome these limitations, products with a high aspect ratio, an excellent step coverage and a three-dimensional structure have been produced. There is a need for hafnium-containing oxide thin films suitable therefor. Accordingly, there is a need for hafnium-containing precursors suitable for process temperatures for various application fields, and there is a need for hafnium-containing precursors which have excellent thermal stability and are usable for atomic layer deposition (ALD) capable of securing a wide process window to overcome a step coverage caused by a high aspect ratio. When a hafnium-containing oxide thin film is formed by ALD, it is expected to improve the thickness uniformity and physical properties of the thin film and improve the properties of semiconductor devices over a wide process temperature range. Also, high-k materials are required for high integration and scaling down of devices. Therefore, the development of a new hafnium precursor is essential. Further, ALD that has self-limiting mechanism and is capable of forming a uniform thin film needs to be used in order to secure the process temperature, dielectric properties and diffusion barrier properties that may occur during a process, and appropriate hafnium precursors need to be used therefor. Accordingly, many studies are being conducted to develop a precursor compound for forming a hafnium-containing oxide thin film that makes it possible to obtain a film having desired properties by ALD.

### DISCLOSURE OF THE INVENTION

### Problems to be Solved by the Invention

The present disclosure provides to a hafnium precursor compound, a precursor composition for forming hafnium-containing film including the hafnium precursor compound and a method of forming a hafnium-containing film using the precursor composition for forming a film.

However, problems to be solved by the present disclosure are not limited to the above-described problems. Although not described herein, other problems to be solved by the present disclosure can be clearly understood by a person with ordinary skill in the art from the following description.

### Means for Solving the Problems

A first aspect of the present disclosure provides a hafnium precursor compound represented by the following Chemical Formula 1:

(R¹R²N)ₓHf(NR³R⁴)₄₋ₓ; [Chemical Formula 1]
in the above Chemical Formula 1,
x is 1, 2, or 3,
each of R¹, R², R³ and R⁴ is independently a linear or branched C₁-C₅ alkyl group, and
—NR¹R² and —NR³R⁴ are different from each other.

A second aspect of the present disclosure provides a precursor composition for forming a hafnium-containing film, including a hafnium precursor compound according to the first aspect.

A third aspect of the present disclosure provides a method of forming a hafnium-containing film, including forming a hafnium-containing film using a precursor composition for forming a hafnium-containing film including a hafnium precursor compound according to the first aspect.

### Effects of the Invention

A hafnium-containing film can be formed by using a hafnium precursor compound according to embodiments of the present disclosure. A hafnium-containing film can be formed at a relatively low temperature by using the hafnium precursor compound according to the embodiments of the present disclosure. A high-quality hafnium-containing film can be formed even at a relatively low temperature of about 200° C. to about 300° C. by using the hafnium precursor compound according to the embodiments of the present disclosure.

The hafnium precursor compound according to the embodiments of the present disclosure can be used as a precursor for atomic layer deposition (ALD) or chemical vapor deposition (CVD) due to its high vapor pressure, low density, and high thermal stability.

When a hafnium-containing film, particularly, a hafnium oxide film is formed by using the hafnium precursor compound according to the embodiments of the present disclosure, the carbon content in the formed film can be reduced. Also, when a hafnium-containing film, particularly, a hafnium oxide film is formed by using the hafnium precursor compound according to the embodiments of the present disclosure by ALD using ozone, the carbon content in the formed film can be reduced.

A thin film deposition method using the hafnium precursor compound according to the embodiments of the present disclosure is depositing a hafnium-containing oxide thin film or nitride thin film on a substrate by ALD using the hafnium precursor compound. When a hafnium-containing metal film or thin film, a hafnium-containing oxide film or thin film, a hafnium-containing nitride film or thin film, a hafnium-containing carbide film or thin film, a hafnium-containing oxynitride film or thin film, and a hafnium-containing carbonitride film or thin film are formed by ALD as described above, the process temperature can be lowered and the thickness and composition of the thin film can be accurately controlled during deposition. Therefore, it is possible to form a thin film with an excellent coverage even on a substrate having a complicated shape and also possible to improve the thickness uniformity and properties of the thin film.

The thin film deposition method using the hafnium precursor compound according to the embodiments of the present disclosure can be used for manufacturing memory devices, logic device, display devices, or OLEDs.

### BRIEF DESCRIPTION OF THE DRAWINGS

FIG. 1 shows the growth per cycle depending on the temperature of each of hafnium precursors prepared by methods of Examples 1, 2, 3, 5, and 6 among Examples of the present disclosure.

FIG. 2A and FIG. 2B show the results of XPS surface analysis of HfO₂ thin films formed by using the hafnium precursors prepared by the methods of Examples 1, 2, 3, and 5 among Examples of the present disclosure.

FIG. 3 shows the results of SIMS element analysis of HfO₂ thin films formed by using CpHf(NMe₂)₃ and the hafnium precursors prepared by the methods of Examples 2, 3, and 6 among Examples of the present disclosure.

### BEST MODE FOR CARRYING OUT THE INVENTION

Hereinafter, embodiments and examples of the present disclosure will be described in detail with reference to the accompanying drawings so that the present disclosure may be readily implemented by those skilled in the art. However, it is to be noted that the present disclosure is not limited to the examples but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the other element and a case that any other element exists between these two elements.

Through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through this whole document, a phrase in the form “A and/or B” means “A or B, or A and B”.

Through the whole document, the term “film” or “thin film” refers to both “film” and “thin film” unless otherwise noted.

Through the whole document, the term “alkyl” or “alkyl group” includes a linear or branched alkyl group having 1 to 12 carbon atoms, 1 to 10 carbon atoms, 1 to 8 carbon atoms, or 1 to 5 carbon atoms and all the possible isomers thereof. For example, the alkyl or alkyl group may include a methyl group (Me), an ethyl group (Et), a n-propyl group (ⁿPr), an iso-propyl group (ⁱPr), a n-butyl group (ⁿBu), an iso-butyl group (ⁱBu), a tert-butyl group (^{t}Bu), a sec-butyl group (^{sec}Bu), a n-pentyl group (ⁿPe), an iso-pentyl group (^{iso}Pe), a sec-pentyl group (^{sec}Pe), a tert-pentyl group (^{t}Pe), a neo-pentyl group (^{neo}Pe), a 3-pentyl group, a n-hexyl group, an iso-hexyl group, a heptyl group, a 4,4-dimethyl pentyl group, an octyl group, a 2,2,4-trimethyl pentyl group, a nonyl group, a decyl group, an undecyl group, a dodecyl group, and isomers thereof, but may not be limited thereto.

Through the whole document, the term “ALD window” may refer to a temperature range suitable for an ALD process to be performed, and is an important factor for the ALD process because aspects of a reaction and properties of a film to be formed or deposited vary depending on the temperature of the ALD process.

Hereinafter, embodiments of the present disclosure have been described in detail, but the present disclosure may not be limited thereto.

A first aspect of the present disclosure provides a hafnium precursor compound represented by the following Chemical Formula 1:

(R¹R²N)ₓHf(NR³R⁴)₄₋ₓ; [Chemical Formula 1]
in the above Chemical Formula 1,
x is 1, 2, or 3,
each of R¹, R², R³ and R⁴ is independently a linear or branched C₁-C₅ alkyl group, and
—NR¹R² and —NR³R⁴ are different from each other.

In an embodiment of the present disclosure, in the above Chemical Formula 1, each of R¹ and R² may be independently methyl group, ethyl group, n-propyl group, iso-propyl group, n-butyl group, iso-butyl group, sec-butyl group, tert-butyl group, n-pentyl group, iso-pentyl group, sec-pentyl group, tert-pentyl group, neo-pentyl group, or 3-pentyl group, and each of R³ and R⁴ may be independently methyl group, ethyl group, n-propyl group, iso-propyl group, n-butyl group, iso-butyl group, sec-butyl group, tert-butyl group, n-pentyl group, iso-pentyl group, sec-pentyl group, tert-pentyl group, neo-pentyl group, or 3-pentyl group.

In an embodiment of the present disclosure, —NR¹R² may be —NMeEt, and —NR³R⁴ may be —N(^{iso}Pr)₂, —NEt(^{iso}Pr), —N(^{iso}Pr)(^{tert}Bu), —NEt(^{tert}Bu), —N(^{sec}Bu)₂, or —N(^{iso}Bu)₂, but may not be limited thereto.

In an embodiment of the present disclosure, the hafnium precursor compound may be selected from the following compounds, but may not be limited thereto:

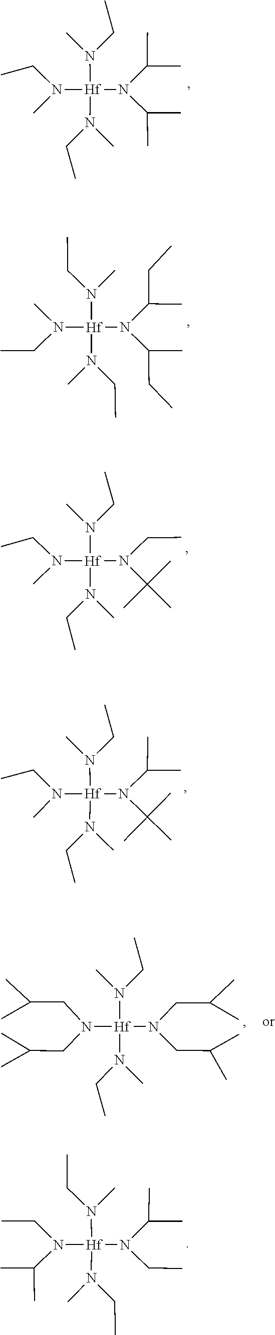

A second aspect of the present disclosure provides precursor composition for forming a hafnium-containing film, including a hafnium precursor compound according to the first aspect.

Detailed descriptions of the second aspect of the present disclosure, which overlap with those of the first aspect of the present disclosure, are omitted hereinafter, but the descriptions of the first aspect of the present disclosure may be identically applied to the second aspect of the present disclosure, even though they are omitted hereinafter.

In an embodiment of the present disclosure, the hafnium precursor compound may include at least one selected from the following compounds, but may not be limited thereto:

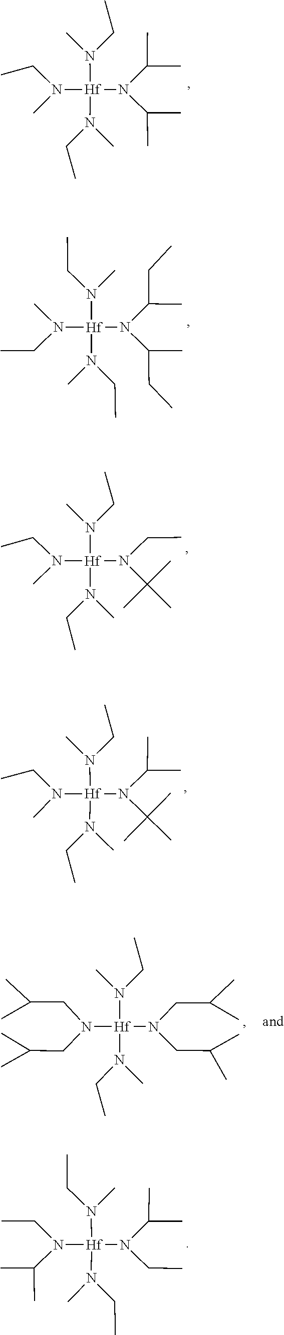

In an embodiment of the present disclosure, the film may include at least one selected from a hafnium-containing metal film or thin film, a hafnium-containing oxide film or thin film, a hafnium-containing nitride film or thin film, a hafnium-containing carbide film or thin film, a hafnium-containing oxynitride film or thin film, and a hafnium-containing carbonitride film or thin film, but may not be limited thereto. In an embodiment of the present disclosure, the hafnium-containing film may be hafnium oxide film.

In embodiments of the present disclosure, the hafnium-containing metal film or thin film, the hafnium-containing oxide film or thin film, the hafnium-containing nitride film or thin film, the hafnium-containing carbide film or thin film, the hafnium-containing oxynitride film or thin film, and the hafnium-containing carbonitride film or thin film may be used for memory, logic, semiconductor, non-semiconductor, and display devices, and can be variously applied depending on the purpose of application. However, the present disclosure may not be limited thereto.

In an embodiment of the present disclosure, the precursor composition may further include at least one nitrogen source(s) selected from ammonia, nitrogen, hydrazine, and dimethyl hydrazine. However, the present disclosure may not be limited thereto.

In an embodiment of the present disclosure, the precursor composition may further include at least one oxygen source(s) selected from water vapor, oxygen, and ozone. However, the present disclosure may not be limited thereto.

A Third aspect of the present disclosure provides a method of forming a hafnium-containing film, including forming a hafnium-containing film using a precursor composition for forming a film including a hafnium precursor compound according to the first aspect.

In an embodiment of the present disclosure, the hafnium precursor compound contained in the precursor composition for forming a film may include at least one selected from the following compounds, but may not be limited thereto:

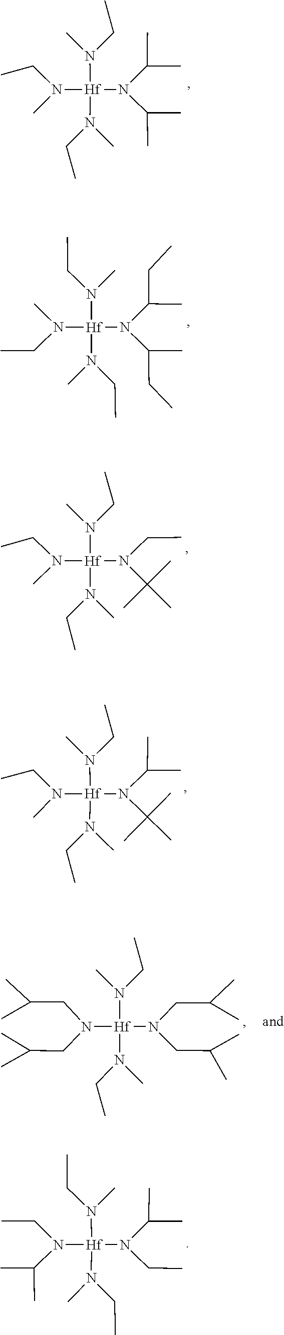

In an embodiment of the present disclosure, the hafnium-containing film may be deposited by chemical vapor deposition (CVD) or atomic layer deposition (ALD), but may not be limited thereto. The CVD or ALD may be performed using a deposition apparatus, deposition conditions and additional reaction gas known in the art, etc.

In an embodiment of the present disclosure, desirably, at least one selected from water vapor (H₂O), oxygen (O₂), O₂ plasma, nitrogen oxides (NO, N₂O), N₂O plasma, oxygen nitride (N₂O₂), hydrogen peroxide (H₂O₂), sulfuric acid (H₂SO₄) and ozone (O₃) may be used as a reaction gas in order to form a hafnium-containing oxide film or a complex metal hafnium-containing oxide film(HfSiOₓ, ZrHfOₓ, TiHfOₓ, HfAlOₓ, ZrAlHfOₓ, TiAlHfOₓ, ZrHfSiOₓ, ZrHfAlSiOₓ, HfC, HfCO, or HfON etc.) when the hafnium-containing film is deposited.

In an embodiment of the present disclosure, it is more desirable to use argon (Ar) or nitrogen (N₂) for delivery, use heat energy or plasma, or apply a bias onto the substrate in order to vaporize the hafnium precursor compound.

In an embodiment of the present disclosure, the hafnium-containing film may be formed in a temperature range of 100° C. to 500° C., but may not be limited thereto. Specifically, the hafnium-containing film may be formed in a temperature range of about 100° C. to about 500° C., about 100° C. to about 450° C., about 100° C. to about 400° C., about 100° C. to about 350° C., about 100° C. to about 300° C., about 100° C. to about 250° C., about 100° C. to about 200° C., about 100° C. to about 150° C., about 150° C. to about 500° C., about 150° C. to about 450° C., about 150° C. to about 400° C., about 150° C. to about 350° C., about 150° C. to about 300° C., about 150° C. to about 250° C., about 150° C. to about 200° C., about 200° C. to about 500° C., about 200° C. to about 450° C., about 200° C. to about 400° C., about 200° C. to about 350° C., about 200° C. to about 300° C., about 200° C. to about 250° C., about 250° C. to about 500° C., about 250° C. to about 450° C., about 250° C. to about 400° C., about 250° C. to about 350° C., about 250° C. to about 300° C., about 300° C. to about 500° C., about 300° C. to about 450° C., about 300° C. to about 400° C., about 300° C. to about 350° C., about 350° C. to about 500° C., about 350° C. to about 450° C., about 350° C. to about 400° C., about 400° C. to about 500° C., about 400° C. to about 450° C., or about 450° C. to about 500° C., but may not be limited thereto. In an embodiment of the present disclosure, the hafnium-containing film may be formed in a temperature range of about 200° C. to about 300° C., about 200° C. to about 280° C., about 200° C. to about 260° C., about 220° C. to about 280° C., or about 240° C. to about 280° C.

In an embodiment of the present disclosure, in the method of forming a hafnium-containing film, desirably, after the substrate is contained in a reaction chamber, the hafnium precursor compound may be delivered onto the substrate with a carrier gas or a diluent gas and a hafnium-containing oxide thin film or nitride thin film may be deposited over a range of deposition temperature of about 100° C. to about 500° C., or about 200° C. to about 300° C. Here, the deposition temperature ranging about 100° C. to about 500° C., or about 200° C. to about 300° C. has great potential for application in various fields by widely expanding a range of process temperatures applicable to memory devices, logic devices, and display devices. Since a hafnium precursor compound that can be used in a wide temperature range is needed, it is desirable that the film should be deposited in a deposition temperature range of about 100° C. to about 500° C., or about 200° C. to about 300° C. Also, at least one mixed gas(es) selected from argon (Ar), nitrogen (N₂), helium (He) or hydrogen (H₂) may be desirably used as the carrier gas or diluent gas.

In an embodiment of the present disclosure, the hafnium-containing film may be formed on at least one substrate(s) selected from conventional hafnium semiconductor wafers, compound semiconductor wafers, and plastic substrates (PI, PET, PES, and PEN), but may not be limited thereto. Also, a substrate having holes or grooves (trenches) may be used, and a porous substrate having a large surface area may also be used, but may not be limited thereto. Further, the hafnium-containing film may be formed simultaneously or sequentially on all or a part of a substrate in which two or more different types of substrates are contacted or connected with each other, but may not be limited thereto.

In an embodiment of the present disclosure, the hafnium-containing film may be formed in a thickness range of about 1 nm to about 500 nm, but may not be limited thereto. The hafnium-containing film may be formed in a thickness range of about 1 nm to about 500 nm, about 1 nm to about 400 nm, about 1 nm to about 300 nm, about 1 nm to about 200 nm, about 1 nm to about 100 nm, about 1 nm to about 50 nm, about 1 nm to about 40 nm, about 1 nm to about 30 nm, about 1 nm to about 20 nm, about 1 nm to about 10 nm, about 10 nm to about 500 nm, about 10 nm to about 400 nm, about 10 nm to about 300 nm, about 10 nm to about 200 nm, about 10 nm to about 100 nm, about 10 nm to about 50 nm, about 10 nm to about 40 nm, about 10 nm to about 30 nm, about 10 nm to about 20 nm, about 20 nm to about 500 nm, about 20 nm to about 400 nm, about 20 nm to about 300 nm, about 20 nm to about 200 nm, about 20 nm to about 100 nm, about 20 nm to about 50 nm, about 20 nm to about 40 nm, about 20 nm to about 30 nm, about 30 nm to about 500 nm, about 30 nm to about 400 nm, about 30 nm to about 300 nm, about 30 nm to about 200 nm, about 30 nm to about 100 nm, about 30 nm to about 50 nm, about 30 nm to about 40 nm, about 40 nm to about 500 nm, about 40 nm to about 400 nm, about 40 nm to about 300 nm, about 40 nm to about 200 nm, about 40 nm to about 100 nm, about 40 nm to about 50 nm, about 50 nm to about 500 nm, about 50 nm to about 400 nm, about 50 nm to about 300 nm, about 50 nm to about 200 nm, about 50 nm to about 100 nm, about 100 nm to about 500 nm, about 100 nm to about 400 nm, about 100 nm to about 300 nm, about 100 nm to about 200 nm, about 200 m to about 500 nm, about 200 nm to about 400 nm, about 200 nm to about 300 nm, about 300 nm to about 500 nm, about 300 nm to about 400 nm, or about 400 nm to about 500 nm, but may not be limited thereto.

In an embodiment of the present disclosure, the hafnium-containing film may be formed on at least one substrate(s) selected from conventional hafnium semiconductor wafers, compound semiconductor wafers, and plastic substrates (PI, PET, PES, and PEN), but may not be limited thereto. Also, a substrate having holes or grooves (trenches) may be used, and a porous substrate having a large surface area may also be used, but may not be limited thereto. Further, the hafnium-containing film may be formed simultaneously or sequentially on all or a part of a substrate in which two or more different types of substrates are contacted or connected with each other, but may not be limited thereto.

In an embodiment of the present disclosure, the hafnium-containing film may be formed on a substrate including a groove (trench) with an aspect ratio of about 1 or more and a width of about 1 μm or less, but may not be limited thereto. For example, the aspect ratio may be about 1 or more, about 5 or more, about 10 or more, about 20 or more, about 30 or more, about 40 or more, about 1 to about 50, about 1 to about 40, about 1 to about 30, about 1 to about 20, about 1 to about 10, about 10 to about 50, about 10 to about 40, about 10 to about 30, about 10 to about 20, about 20 to about 50, about 20 to about 40, about 20 to about 30, about 30 to about 50, about 30 to about 40, or about 40 to about 50, but may not be limited thereto. Further, For example, the width may be about 1 μm or less, about 900 nm or less, about 800 nm or less, about 700 nm or less, about 600 nm or less, about 500 nm or less, about 400 nm or less, about 300 nm or less, about 200 nm or less, about 100 nm or less, about 10 nm to about 1 μm, about 10 nm to about 900 nm, about 10 nm to about 800 nm, about 10 nm to about 700 nm, about 10 nm to about 600 nm, about 10 nm to about 500 nm, about 10 nm to about 400 nm, about 10 nm to about 300 nm, about 10 nm to about 200 nm, about 10 nm to about 100 nm, about 10 nm to about 90 nm, about 10 nm to about 80 nm, about 10 nm to about 70 nm, about 10 nm to about 60 nm, about 10 to about 50 nm, about 10 nm to about 40 nm, about 10 nm to about 30 nm, about 10 nm to about 20 nm, about 20 nm to about 1 μm, about 20 nm to about 900 nm, about 20 nm to about 800 nm, about 20 nm to about 700 nm, about 20 nm to about 600 nm, about 20 nm to about 500 nm, about 20 nm to about 400 nm, about 20 nm to about 300 nm, about 20 nm to about 200 nm, about 20 nm to about 100 nm, about 20 nm to about 90 nm, about 20 nm to about 80 nm, about 20 nm to about 70 nm, about 20 nm to about 60 nm, about 20 to about 50 nm, about 20 nm to about 40 nm, about 20 nm to about 30 nm, about 30 nm to about 1 μm, about 30 nm to about 900 nm, about 30 nm to about 800 nm, about 30 nm to about 700 nm, about 30 nm to about 600 nm, about 30 nm to about 500 nm, about 30 nm to about 400 nm, about 30 nm to about 300 nm, about 30 nm to about 200 nm, about 30 nm to about 100 nm, about 30 nm to about 90 nm, about 30 nm to about 80 nm, about 30 nm to about 70 nm, about 30 nm to about 60 nm, about 30 to about 50 nm, about 30 nm to about 40 nm, about 40 nm to about 1 μm, about 40 nm to about 900 nm, about 40 nm to about 800 nm, about 40 nm to about 700 nm, about 40 nm to about 600 nm, about 40 nm to about 500 nm, about 40 nm to about 400 nm, about 40 nm to about 300 nm, about 40 nm to about 200 nm, about 40 nm to about 100 nm, about 40 nm to about 90 nm, about 40 nm to about 80 nm, about 40 nm to about 70 nm, about 40 nm to about 60 nm, about 40 to about 50 nm, about 50 nm to about 1 μm, about 50 nm to about 900 nm, about 50 nm to about 800 nm, about 50 nm to about 700 nm, about 50 nm to about 600 nm, about 50 nm to about 500 nm, about 50 nm to about 400 nm, about 50 nm to about 300 nm, about 50 nm to about 200 nm, about 50 nm to about 100 nm, about 50 nm to about 90 nm, about 50 nm to about 80 nm, about 50 nm to about 70 nm, about 50 nm to about 60 nm, about 100 nm to about 1 μm, about 100 nm to about 900 nm, about 100 nm to about 800 nm, about 100 nm to about 700 nm, about 100 nm to about 600 nm, about 100 nm to about 500 nm, about 100 nm to about 400 nm, about 100 nm to about 300 nm, about 100 nm to about 200 nm, about 200 nm to about 1 μm, about 200 nm to about 900 nm, about 200 nm to about 800 nm, about 200 nm to about 700 nm, about 200 nm to about 600 nm, about 200 nm to about 500 nm, about 200 nm to about 400 nm, about 200 nm to about 300 nm, about 300 nm to about 1 μm, about 300 nm to about 900 nm, about 300 nm to about 800 nm, about 300 nm to about 700 nm, about 300 nm to about 600 nm, about 300 nm to about 500 nm, about 300 nm to about 400 nm, about 400 nm to about 1 μm, about 400 nm to about 900 nm, about 400 nm to about 800 nm, about 400 nm to about 700 nm, about 400 nm to about 600 nm, about 400 nm to about 500 nm, about 500 nm to about 1 μm, about 500 nm to about 900 nm, about 500 nm to about 800 nm, about 500 nm to about 700 nm, about 500 nm to about 600 nm, about 600 nm to about 1 μm, about 600 nm to about 900 nm, about 600 nm to about 800 nm, about 600 nm to about 700 nm, about 700 nm to about 1 μm, about 700 nm to about 900 nm, about 700 nm to about 800 nm, about 800 nm to about 1 μm, about 800 nm to about 900 nm, or about 900 nm to about 1 μm, but may not be limited thereto.

In the embodiments of the present disclosure, the hafnium precursor compound of the present disclosure contained in the precursor composition for forming a film is used as a precursor of ALD or CVD due to its high vapor pressure, low density, and high thermal stability to form a hafnium-containing film. In particular, a hafnium-containing metal film or thin film, a hafnium-containing oxide film or thin film, a hafnium-containing nitride film or thin film, a hafnium-containing carbide film or thin film, a hafnium-containing oxynitride film or thin film, and a hafnium-containing carbonitride film or thin film having a thickness of several nm to several tens of am or about 1 nm to about 500 nm can be uniformly formed on a substrate having a pattern (grooves), a porous substrate, or a plastic substrate in a wide temperature range of about 100° C. to about 500° C.

Hereinafter, the present disclosure will be explained in more detail with reference to Examples. However, the following Examples are illustrative only for better understanding of the present disclosure but do not limit the present disclosure.

### MODE FOR CARRYING OUT THE INVENTION

### Example

### Example 1: Preparation of (diisopropylamino)tris(ethyl(methyl)amino)hafnium: [{((CH₃)₂HC)₂N}Hf{N(C₂H₅)(CH₃)}₃]

In a 3-L round-bottom flask, 50 g (0.156 mol) of hafnium (IV) chloride (HfCl₄) was dissolved in 500 mL of diethyl ether at about −20° C., and 500 mL of tetrahydrofurane was slowly added thereto, and then, the temperature was slowly raised to room temperature with stirring, followed by stirring for 1 hour. Thereafter, 192.42 g (0.468 mol) of tetrakis(ethyl(methyl)amino)hafnium (Hf{N(Et)(Me)}₄) was slowly added to the solution at about −20° C., and the temperature was slowly raised to room temperature with stirring, followed by stirring for 17 hours to prepare a tris(ethyl(methyl)amino)hafnium(IV) chloride (Hf{N(Et)(Me)}₃Cl) solution.

Also, in another 2-L round-bottom flask, 173.9 g (2.5 M, 0.624 mol) of n-BuLi in n-hex. was mixed with 500 mL of anhydrous hexane. After 63.18 g (0.624 mol) of diisopropylamine was slowly added at about −20° C., the temperature was slowly raised to room temperature with stirring, followed by stirring for 4 hours. After a prepared lithium diisopropylamide (LiN(ⁱPr)₂) solution was slowly added to the above-synthesized tris(ethyl(methyl)amino)hafnium(IV) chloride solution at about −20° C., the temperature was gradually raised to room temperature, followed by reflux using a reflux condenser for 17 hours. After completion of the reaction, the resultant salt was removed by filtration and the solvent and volatile by-products were removed by distillation under reduced pressure to obtain 172.52 g (yield: 61%) of (diisopropylamino)tris((ethyl)(methyl)amino)hafnium ({(ⁱPr)₂N}Hf{N(Et)(Me)}₃) which is a colorless liquid compound represented by the following Chemical Formula 2.

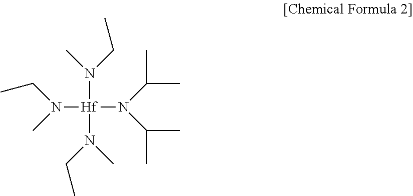

b.p: 100° C. at 0.282 torr (308.9° C. at 760 mmHg)

¹H-NMR (C₆D₆): δ1.150 (N—CH₂—CH₃, t, 9H), δ1.226, 1.242 (N—CH—CH₃, d, 12H), δ3.016 (N—CH₃, s, 9H), δ3.335, 3.352 (N—CH₂—CH₃, q, 6H), δ3.503 (N—CH—CH₃, m, 2H)

### Example 2: Preparation of (disecbutylamino)tris(ethyl(methyl)amino)hafnium: [{((C₂H₅)(CH₃)HC)₂N}Hf{N(C₂H₅)(CH₃)}3]

174.88 g (yield: 58%) of (disecbutylamino)tris((ethyl)(methyl)amino)hafnium ({(^{sec}Bu)₂N}Hf{N(Et)(Me)}₃) which is a colorless liquid compound represented by the following Chemical Formula 3 was obtained by the same method as in Example 1 except that disecbutylamine was used instead of diisopropylamine.

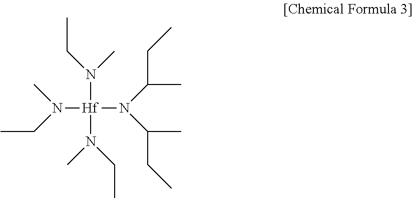

b.p: 110° C. at 0.313 torr (321.0° C. at 760 mmHg)

¹H-NMR (C₆D₆): δ 0.946 (N—CH—CH₂—CH₃, t, 6H), δ1.141 (N—CH₂—CH₃, t, 9H), δ1.227 (N—CH—CH₃, t, 6H), δ1.519, 1.593 (N—CH—CH₂—CH₃, m, 4H), δ3.004 (N—CH₃, s, 9H), δ3.096(N—CH—CH₃, m, 2H), δ3.329, 3.346 (N—CH₂—CH₃, q, 6H)

### Example 3: Preparation of (tert-butyl(ethyl)amino)tris(ethyl(methyl)amino)hafnium: [{((CH₃)₃C)(C₂H₅)N}Hf{N(C₂H₅)(CH₃)}₃]

100 g (yield: 61%) of (tert-butyl(ethyl)amino)tris((ethyl)(methyl)amino)hafnium ({(^{t}Bu)(Et)N}Hf{N(Et)(Me)}₃]) which is a colorless liquid compound represented by the following Chemical Formula 4 was obtained by the same method as in Example 1 except that tert-butyl(ethyl)amine was used instead of diisopropylamine.

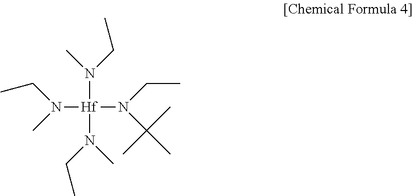

b.p: 95° C. at 0.308 torr (300.2° C. at 760 mmHg)

¹H-NMR (C₆D₆): δ1.147 (N—CH₂—CH₃, t, 9H), δ1.250 (N—CH₂—CH₃, t, 3H), δ1.263 (N—C—CH₃, s, 9H), δ3.000 (N—CH₃, s, 9H), δ3.240, 3.258 (N—CH₂—CH₃, q, 2H), δ3.314, 3.332 (N—CH₂—CH₃, q, 6H)

### Example 4: Preparation of (tert-butyl(isopropyl)amino)tris(ethyl(methyl)amino)hafnium: [{((CH₃)₃C)((CH₃)₂HC)N}Hf{N(C₂H₅)(CH₃)}₃]

65.7 g (yield: 61%) of (tert-butyl(isopropyl)amino)tris((ethyl)(methyl)amino)hafnium ({(^{t}Bu)(ⁱPr)N}Hf{N(Et)(Me)}₃) which is a yellow solid compound represented by the following Chemical Formula 5 was obtained by the same method as in Example 1 except that tert-butyl(isopropyl)amine was used instead of diisopropylamine.

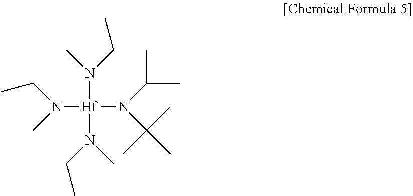

b.p: 110° C. at 0.3 torr (322° C. at 760 mmHg)

¹H-NMR (C₆D₆): δ1.107 (N—CH₂—CH₃, t, 9H), δ1.259 (N—C—CH₃, s, 9H), δ1.294, 1.310 (N—CH—CH₃, d, 6H), δ2.984 (N—CH₃, s, 9H), δ3.246 (N—CH—CH₃, m, H), δ3.312, 3.329 (N—CH₂—CH₃, q, 6H)

### Example 5: Preparation of bis(diisobutylamino)bis(ethyl(methyl)amino)hafnium: [{((CH₃)₂CHCH₂)₂N}₂Hf{N(C₂H₅)(CH₃)}₂]

In a 3-L round-bottom flask, 50 g (0.156 mol) of hafnium (IV) chloride (HfCl₄) was dissolved in 500 mL of diethyl ether at about −20° C., and 500 mL of tetrahydrofurane was slowly added thereto, and then, the temperature was slowly raised to room temperature with stirring, followed by stirring for 1 hour. Thereafter, 64.14 g (0.156 mol) of tetrakis(ethyl(methyl)amino)hafnium (Hf{N(Et)(Me)}₄) was slowly added to the solution at about −20° C., and the temperature was slowly raised to room temperature with stirring, followed by stirring for 17 hours to prepare a bis((ethyl)(methyl)amino)hafnium(IV) chloride (Hf{N(Et)(Me)}₂Cl₂) solution.

Also, in another 2-L round-bottom flask, 173.9 g (2.5 M, 0.624 mol) of n-BuLi in n-hex. was mixed with 500 mL of anhydrous hexane. After 80.69 g (0.624 mol) of diisobutylamine was slowly added at about −20° C., the temperature was slowly raised to room temperature with stirring, followed by stirring for 4 hours. After a prepared lithium diisobutylamide (LiN(ⁱBu)₂) solution was slowly added to the above-synthesized bis(ethyl(methyl)amino)hafnium(IV) chloride solution at about −20° C., the temperature was gradually raised to room temperature, followed by reflux using a reflux condenser for 17 hours. After completion of the reaction, the resultant salt was removed by filtration and the solvent and volatile by-products were removed by distillation under reduced pressure to obtain 111.84 g (yield: 65%) of bis(diisobutylamino)bis(ethyl(methyl)amino)hafnium ({(ⁱBu)₂N}₂Hf{N(Et)(Me)}₂) which is a yellow liquid compound represented by the following Chemical Formula 6.

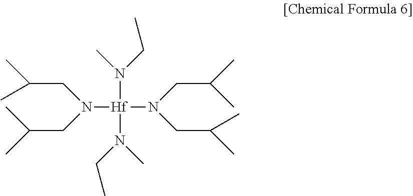

b.p: 122° C. at 0.1 torr (360.3° C. at 760 mmHg)

¹H-NMR (C₆D₆): δ0.977, 0.994 (N—CH₂—CH—CH₃, d, 24H), δ1.144 (N—CH₂—CH₃, t, 6H), δ1.846 (N—CH₂—CH—CH₃, m, 4H), δ2.980 (N—CH₃, s, 6H), δ3.104, 3.122 (N—CH₂—CH—CH₃, d, 8H), δ3.342, 3.359 (N—CH₂—CH₃, q, 4H)

### Example 6: bis(ethyl(isopropyl)amino)bis(ethyl(methyl)amino)hafnium: [{(C₂HO)((CH₃)₂HC)N}₂Hf{N(C₂H)(CH₃)}₂]

55.13 g (yield: 51%) of bis (ethyl(isopropyl)amino)bis((ethyl)(methyl)amino)hafnium ({(Et)(ⁱPr)N}₂Hf {N(Et)(Me)}₂) which is a colorless liquid compound represented by the following Chemical Formula 7 was obtained by the same method as in Example 5 except that ethyl(isopropyl)amine was used instead of diisobutylamine.

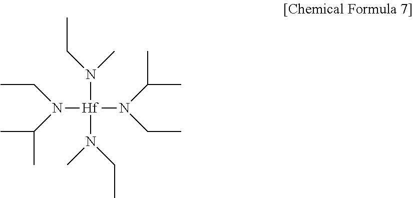

b.p: 95° C. at 0.3 torr (300.9° C. at 760 mmHg)

¹H-NMR (C₆D₆): δ1.169 (N—CH₂—CH₃, t, 6H), δ1.216 (N—CH₂—CH₃, t, 6H), δ1.228, 1.244 (N—CH—CH₃, d, 12H), δ3.000 (N—CH₃, s, 6H), δ3.264, 3.282 (N—CH₂—CH₃, q, 4H), δ3.323, 3.341 (N—CH₂—CH₃, q, 4H), δ3.483 (N—CH—CH₃, m, 2H)

### Test Example

### <Test Example 1> Oxide Film Deposition Characteristics Depending on Temperature of Hafnium Precursor Compounds

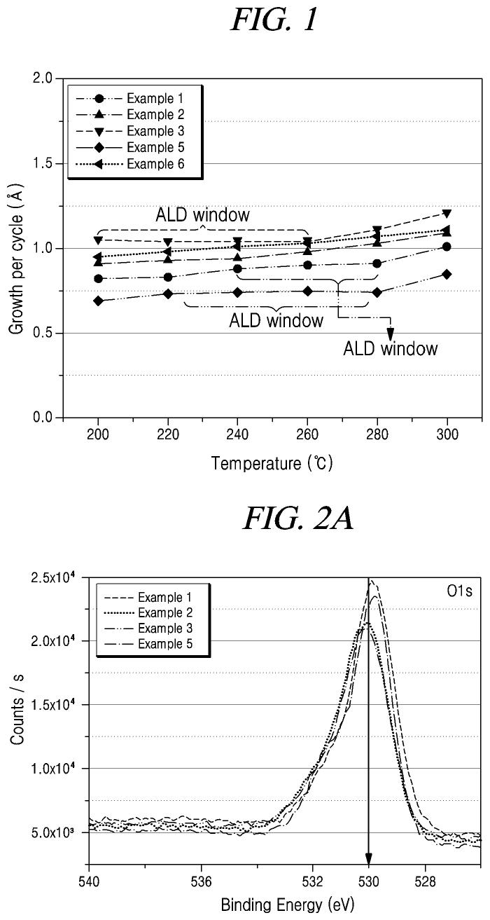

An atomic layer deposition (ALD) process was performed by using the hafnium precursor compounds prepared by the methods of Examples 1, 2, 3, 5, and 6. O₃, which is an oxygen source, was used as the reaction gas. First, a silicon wafer was immersed for 10 minutes in a piranha solution in which sulfuric acid (H₂SO₄) and hydrogen peroxide (H₂O₂) were mixed at a ratio of 4:1 ratio and then taken out. Thereafter, the silicon wafer was immersed in a dilute HF aqueous solution for about 2 minutes to form a pure silicon surface. Then, a hafnium oxide thin film was prepared by ALD. In order to measure deposition characteristics depending on the temperature, the number of ALD cycles was fixed to 100 and the substrate was heated at 20° C. intervals from 200° C. to 300° C. The hafnium precursor compounds were placed in respective containers made of stainless steel and then heated to 100° C., 115° C., 100° C., 135° C., and 105° C., respectively. In this case, the hafnium precursor compounds were vaporized using an argon (Ar) gas having a flow rate of 300 sccm as a carrier gas at a process pressure of 1 torr in the reactor. The ALD cycle was composed of supply of each vaporized precursor for 5 sec, precursor purge for 10 sec, O₃ exposure for 5 sec and O₃ purge for 10 sec. The deposition results are shown in FIG. 1.

As shown in FIG. 1, the ALD window can be seen from the deposition results of the hafnium precursors prepared by the methods of Examples 1, 3, and 5 among the prepared hafnium precursor compounds. This characteristic of showing ALD window at a relatively low temperatures can improve electrical characteristics by suppressing oxidation of a lower electrode when the process is performed at a low temperature. The hafnium precursor compounds prepared by the methods of Examples 1, 2, 3, 5, and 6 are excellent precursors satisfying the above-described characteristics and can be used in various fields of semiconductor technology.

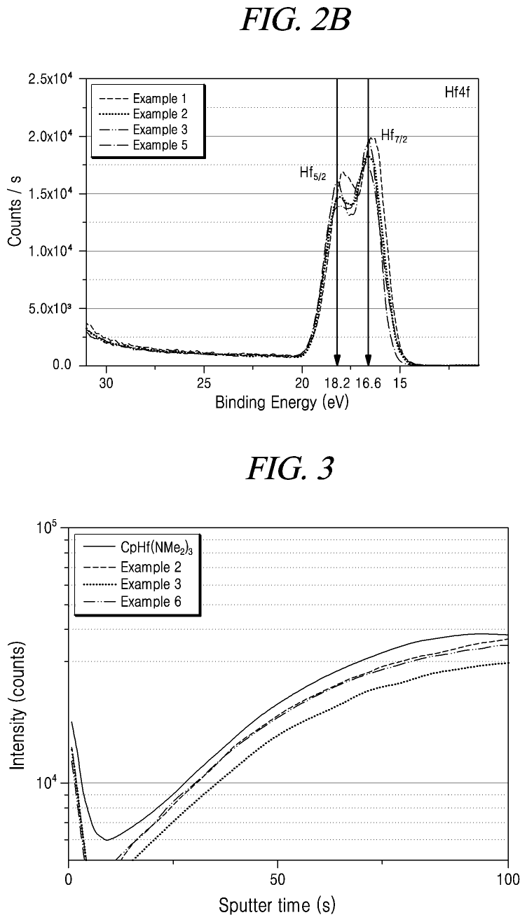

FIG. 2A and FIG. 2B show the results of XPS surface analysis of HfO₂ thin films formed by using the hafnium precursors prepared by the methods of Examples 1, 2, 3, and 5. The XPS analysis was performed with HfO₂ thin films deposited at 240° C. In all of the five thin films analyzed, strong spectra of Hf—O bonding were observed at around 530.0 eV, and Hf peak (18.2 eV) caused by HfO₂ and Hf peak (16.6 eV) caused by Hf suboxide were observed. Also, it was confirmed that they have a ratio of Hf:O of 1:2 and are excellent precursors which can be used for depositing a HfO₂ thin film even at a relatively low temperature.

FIG. 3 shows the results of SIMS element analysis of HfO₂ thin films formed by using CpHf(NMe₂)₃, which is currently commercially available, and the hafnium precursors prepared by the methods of Examples 2, 3, and 6. The SIMS analysis was performed with HfO₂ thin films deposited at 240° C. An element to be compared is carbon. As a result of the analysis, the carbon content in the HfO₂ thin films formed by using the hafnium precursors prepared by the methods of Examples 2, 3, and 6 was lower than the carbon content in the HfO₂ thin film formed by using CpHf(NMe₂)₃. The carbon contents measured based on the sputter time of 75 seconds in the order of CpHf(NMe₂)₃, Examples 2, 3, and 6 were 31937, 28169, 23494, and 27388, respectively, and the reduction rates of the hafnium precursors prepared by the methods of Examples 2, 3, and 6 were lower by 11.8%, 26.4%, and 14.2%, respectively, than that of CpHf(NMe₂)₃. Therefore, the reduction rate of CpHf(NMe₂)₃ was the highest and the reduction rate of Example 3 was the lowest (Example 3<Example 6<Example 2<CpHf(NMe₂)₃). The amount of carbon remaining in a HfO₂ thin film is a factor that degrades electrical characteristics. Therefore, as the carbon content decreases, the electrical characteristics are improved. Since the lower the carbon content, the better the electrical properties, the carbon contents in the hafnium precursors prepared by the methods of Examples 2, 3, and 6 are lower than the carbon content in the standard CpHf(NMe₂)₃, and, thus, the hafnium precursors prepared by the methods of Examples 2, 3, and 6 can be excellent precursors for forming a film with a low carbon content.

The above description of the present disclosure is provided for the purpose of illustration, and it would be understood by a person with ordinary skill in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

What is claimed is:

1. A hafnium precursor compound represented by the following Chemical Formula 1:
(R¹R²N)ₓHf(NR³R⁴)₄₋ₓ; [Chemical Formula 1]
wherein, in the above Chemical Formula 1,
X is 1, 2, or 3,
each of R¹, R², R³ and R⁴ is independently a linear or branched C₁-C₅ alkyl group, and
—NR¹R² and —NR³R⁴ are different from each other.

2. The hafnium precursor compound of claim 1,
wherein in the above Chemical Formula 1,
each of R¹ and R² is independently methyl group, ethyl group, n-propyl group, iso-propyl group, n-butyl group, iso-butyl group, sec-butyl group, tert-butyl group, n-pentyl group, iso-pentyl group, sec-pentyl group, tert-pentyl group, neo-pentyl group, or 3-pentyl group, and
each of R³ and R⁴ is independently methyl group, ethyl group, n-propyl group, iso-propyl group, n-butyl group, iso-butyl group, sec-butyl group, tert-butyl group, n-pentyl group, iso-pentyl group, sec-pentyl group, tert-pentyl group, neo-pentyl group, or 3-pentyl group.

3. The hafnium precursor compound of claim 1,
wherein —NR¹R² is —NMeEt, and
—NR³R⁴ is —N(^{iso}Pr)₂, —NEt(^{iso}Pr), —N(^{iso}Pr)(^{tert}Bu), —NEt(^{tert}Bu), —N(^{sec}Bu)₂, or —N(^{iso}Bu)₂.

4. The hafnium precursor compound of claim 1,
wherein the hafnium precursor compound is selected from the following compounds:

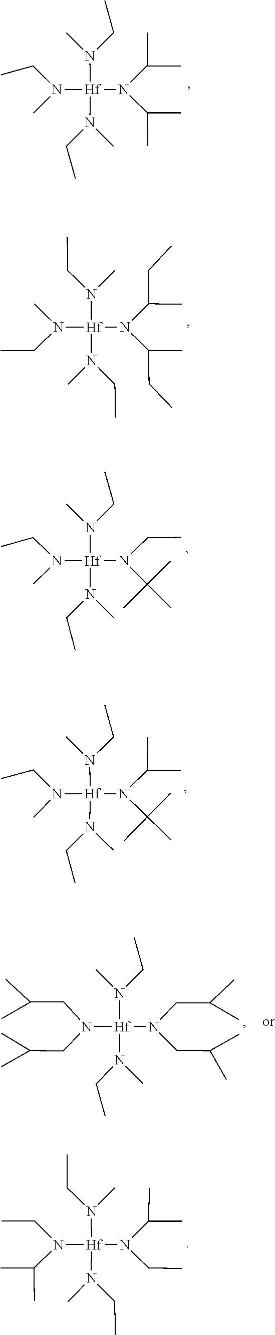

5. A precursor composition for forming a hafnium-containing film, comprising:
a hafnium precursor compound of claim 1.

6. The precursor composition of claim 5,
wherein the hafnium precursor compound includes at least one selected from the following compounds:

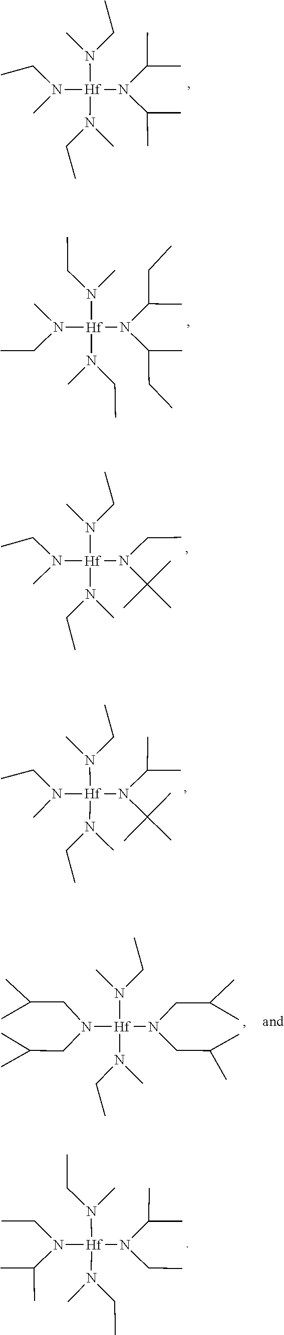

7. The precursor composition of claim 5,
wherein the film includes at least one selected from a hafnium metal film, a hafnium-containing oxide film, a hafnium-containing nitride film, a hafnium-containing carbide film, a hafnium-containing oxynitride film, and a hafnium-containing carbonitride film.

8. The precursor composition of claim 5, further comprising:
at least one nitrogen source(s) selected from ammonia, nitrogen, hydrazine, and dimethyl hydrazine.

9. The precursor composition of claim 5, further comprising:
at least one oxygen source(s) selected from water vapor, oxygen, and ozone.

10. A method of forming a hafnium-containing film, comprising:
forming a hafnium-containing film using a precursor composition for forming a film containing a hafnium precursor compound of claim 1.

11. The method of claim 10,
wherein the hafnium precursor compound contained in the precursor composition for forming a film includes at least one selected from the following compounds:

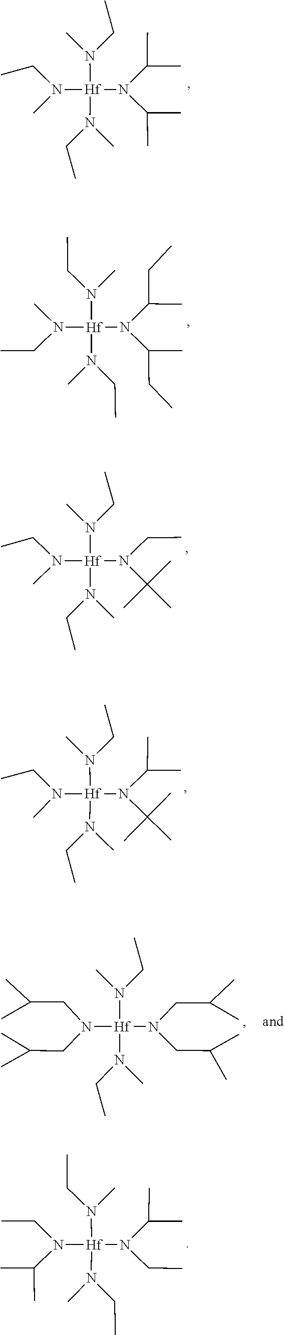

12. The method of claim 10,
wherein the hafnium-containing film is deposited by chemical vapor deposition or atomic layer deposition.

13. The method of claim 10,
wherein the hafnium-containing film is formed in a temperature range of 100° C. to 500° C.

14. The method of claim 10,
wherein the hafnium-containing film is formed in a thickness range of 1 nm to 500 nm.
